(19) United States
(12) Patent Application Publication
(10) Pub. No.: US 2016/0186363 A1
(43) Pub. Date: Jun. 30, 2016

(54) DIAMOND COATING AND METHOD OF DEPOSITING THE SAME

(71) Applicant: THE SWATCH GROUP RESEARCH AND DEVELOPMENT LTD, Marin (CH)

(72) Inventors: Sebastiano MERZAGHI, Lausanne (CH); Cedric FAURE, Cortaillod (CH); Philippe DUBOIS, Marin (CH)

(73) Assignee: The Swatch Group Research and Development Ltd., Marin (CH)

(21) Appl. No.: 14/909,659

(22) PCT Filed: Jul. 2, 2014
(86) PCT No.: PCT/EP2014/064043

§ 371 Date: Feb. 2, 2016

(30) Foreign Application Priority Data
Aug. 2, 2013 (EP) 1317959.2

(51) Int. Cl. C30B 28/14; F16H 55/06; F16H 55/17; C30B 29/04

(52) U.S. Cl. CPC C30B 28/14; C30B 29/04; F16H 55/06; F16H 55/17

(57) ABSTRACT

The invention concerns a diamond coating characterized in that it includes at least one stack of a first nanocrystalline diamond layer and a second microcrystalline diamond layer.

The present invention concerns a diamond coating and in particular a microcrystalline diamond coating (MCD) having a roughness Ra of less than 20 nanometres, for example for tribological applications in the field of m icromechanics.

The invention also concerns a deposition method for such a diamond coating that is economical to implement. The present invention more specifically concerns a method of this type for application to micromechanical parts arranged to be in friction contact with other parts, relative to which the micromechanical parts are in motion. These micromechanical parts may equally well be mobile parts, such as pivoting parts for example, or fixed parts, such as bearings for example. They may be, by way of non-limiting example, micromechanical parts for a mechanical timepiece movement.

The invention also concerns a micromechanical part comprising a substrate having a functional surface coated with a diamond coating.

It is well known in the prior art to coat substrates with a microcrystalline diamond coating to increase the wear resistance of said substrate and also to reduce friction.

FIG. 1 is a schematic illustration of a microcrystalline layer according to the prior art. To create such monocrystalline diamond coatings, a nucleation layer 1 is created on the surface of the substrate 2 to be coated. This nucleation layer for example comprises seeds formed of diamond nanoparticles distributed over the substrate surface with a coating density on the order of 10¹⁰ particles/cm². The substrate is then placed in a hot filament or plasma chemical vapour deposition (CVD) reactor in which a gas mixture, typically a methane-hydrogen mixture, is injected. In determined pressure, temperature and gas flow conditions, diamond microcrystals 3 grow from the seeds in a columnar manner to the desired coating thickness. The microcrystals typically have a pyramidal columnar shape flaring away from the substrate so that grain size increases with the thickness of the layer as illustrated in FIG. 1.

For tribological applications and typical wear resistance, diamond layers having a thickness on the order of 0.5 to 10 micrometres are used. With such thicknesses, the surface grain size exceeds 200 nm and roughness (Ra) may reach values of more than 50 nm, which means that satisfactory friction conditions cannot be achieved in many applications.

To overcome this drawback those skilled in the art are thus obliged to perform one or more subsequent polishing operations on the deposition to reduce roughness. Typically, these polishing operations are performed mechanically or by plasma method. In all cases, these polishing operations are long, difficult, expensive and do not provide a satisfactory result for certain applications, particularly for coating micromechanical timepiece components, such as pallets and/or escape wheel teeth.

It is therefore an object of the present invention to overcome these drawbacks by providing a diamond coating and, in particular, a microcrystalline diamond coating having a roughness Ra of less than 20 nanometres, which is easier to obtain and more economical to implement than prior art coatings.

It is also an object of the invention to provide a microcrystalline diamond coating having improved mechanical properties throughout its thickness.

It is also an object of the invention to provide a microcrystalline diamond coating having on its visible outer surface a grain size of less than 100 nm, regardless of the total thickness of the coating of the invention.

It is also an object of the invention to provide a microcrystalline diamond coating having an outer surface of improved aesthetic appearance, especially having improved reflectivity and suitable for applications in the field of optics.

To this end, the present invention concerns a diamond coating characterized in that it includes at least one stack of a first nanocrystalline diamond layer and a second microcrystalline diamond layer.

As a result of these features, the present invention offers the possibility of creating thick microcrystalline diamond coatings, i.e. of more than 1 micrometer, having a smaller surface grain size and associated roughness than a microcrystalline diamond layer of the same thickness. This is due to the fact that the monocrystalline microcrystal growth is from a nucleation layer formed by the nanocrystalline diamond layer which is much denser than a conventional nucleation layer formed of diamond nanoparticles.

According to a preferred embodiment, the coating of the invention includes a succession of at least two of said stacks wherein the microcrystalline diamond layer of a first stack is in contact with the nanocrystalline diamond layer of the next stack.

Since the pyramidal columnar growth is re-started on each stack forming the coating, this means that the succession of stacks of the invention provide a large coating thickness with the grain size and roughness of a single stack of given thickness.

Advantageously, the thickness of the nanocrystalline layer is comprised between 50 nanometres and 1 micrometre and the thickness of the microcrystalline layer is comprised between 100 nanometres and 1 micrometre, and preferably the thickness of the nanocrystalline layer is comprised between 100 and 200 nanometres and thickness of the microcrystalline layer is comprised between 200 and 500 nanometres.

Preferably, the grain size at the surface of the nanocrystalline diamond layer is less than 50 nanometres and in particular less than 30 nanometres and even more preferably less than 10 nanometres.

Preferably, the grain size of the visible outer surface of the coating of the invention is on the order of 100 nanometres.

The invention also concerns a micromechanical part comprising a substrate having a functional surface, wherein the functional surface is coated with a diamond coating comprising at least one stack of a first nanocrystalline diamond layer and a second microcrystalline diamond layer, said functional surface of the substrate being in contact with the nanocrystalline diamond layer of said coating.

Advantageously, the substrate is selected from among the group of materials comprising silicon, titanium, zirconium, hafnium, vanadium, tantalum, molybdenum, tungsten, boron; borides, carbides, nitrides and oxides of the latter materials, and ceramics.

According to preferred embodiments, the micromechanical part of the invention may be a toothed wheel, a pinion, an escape wheel, a pallet-lever, a pallet-stone, a spring, a mainspring, a balance spring, an arbor and/or pivot bearings.

The invention also concerns a method for depositing a diamond coating on a substrate by chemical vapour deposition in a reaction chamber, the method comprising at least:
a) a step of preparing the substrate,
b) an initial nucleation step,
c) a step of growing the coating on a surface of the substrate, the growth step comprising at least one sequence of two successive phases comprising a phase of nanocrystalline diamond growth to form a nanocrystalline diamond layer, followed by another phase of microcrystalline diamond growth, the nanocrystalline diamond layer being used as a nucleation layer for growth of the microcrystalline diamond layer.

Preferably, step c) is repeated a plurality of times.

Advantageously, during the nanocrystalline diamond growth phase of step c), the deposition parameters are adjusted so that the nanocrystalline diamond grain size does not exceed 50 nanometres and preferably 30 nanometres and even more preferably 10 nanometres, and the duration of the microcrystalline diamond growth phase of step c) is set in order to achieve a microcrystalline diamond thickness comprised between 200 nanometres and 1 micrometre and preferably comprised between 200 and 500 nanometres.

Preferably, the duration of the nanocrystalline diamond growth phase of step c) makes it possible to obtain a nanocrystalline diamond thickness comprised between 100 and 200 nanometres.

Preferably, the substrate is selected from among the group of materials comprising silicon, titanium, zirconium, hafnium, vanadium, tantalum, molybdenum, tungsten, boron; borides, carbides, nitrides and oxides of the latter materials, and ceramics.

Advantageously, the method is implemented in a hot filament reactor and the substrate temperature during step c) is comprised between 500 and 1000° C.

According to a preferred embodiment the nanocrystalline diamond growth phase is implemented in the following conditions:
duration comprised between 1 hour and 5 hours,
heating, respectively direct or indirect activation, of a CH₄/H₂/X gas mixture wherein X represents a dopant gas, with a percentage by volume of dopant gas comprised between 0% and 10%, and with a percentage by volume of CH₄ relative to the total volume comprised between 3% and 9%,
the hydrogen flow rate at 1 bar pressure is comprised between 20 and 50 litres per minute and preferably 40 litres per minute
the pressure of the gas mixture in the chamber is comprised between 2 and 6 mbar,
the substrate temperature is comprised between 500 and 1000° C.,
   and the microcrystalline diamond growth phase is implemented in the following conditions:
duration comprised between 1 hour and 5 hours,
heating, respectively direct or indirect, of a CH₄/H₂/X gas mixture wherein X represents a dopant gas, with a percentage by volume of dopant gas comprised between 0% and 10%, and with a percentage by volume of CH₄ relative to the total volume comprised between 0.05% and 1%,
the hydrogen flow rate at 1 bar pressure is comprised between 30 and 90 litres per minute and preferably 60 litres per minute the pressure of the gas mixture in the chamber is comprised between 0.5 and 2 mbar, and
the substrate temperature is comprised between 500 and 1000° C.

### BRIEF DESCRIPTION OF THE DRAWINGS

The features of the invention will appear more clearly on reading the description of a preferred embodiment of the invention, given solely by way of non-limiting example with reference to the annexed Figures, in which:

FIG. 1, already described, shows a schematic cross-section of a substrate coated with a microcrystalline diamond coating according to the prior art;

FIG. 2 shows a cross-section of a substrate coated with a microcrystalline diamond coating comprising a stack according to the invention;

FIG. 3 shows a cross-section of a substrate coated with a microcrystalline diamond coating comprising a plurality of stacks according to the invention;

FIGS. 4a and 4b are respectively scanning electron microscope photographs showing top views of a substrate coated with a microcrystalline diamond coating according to the invention and according to the prior art.

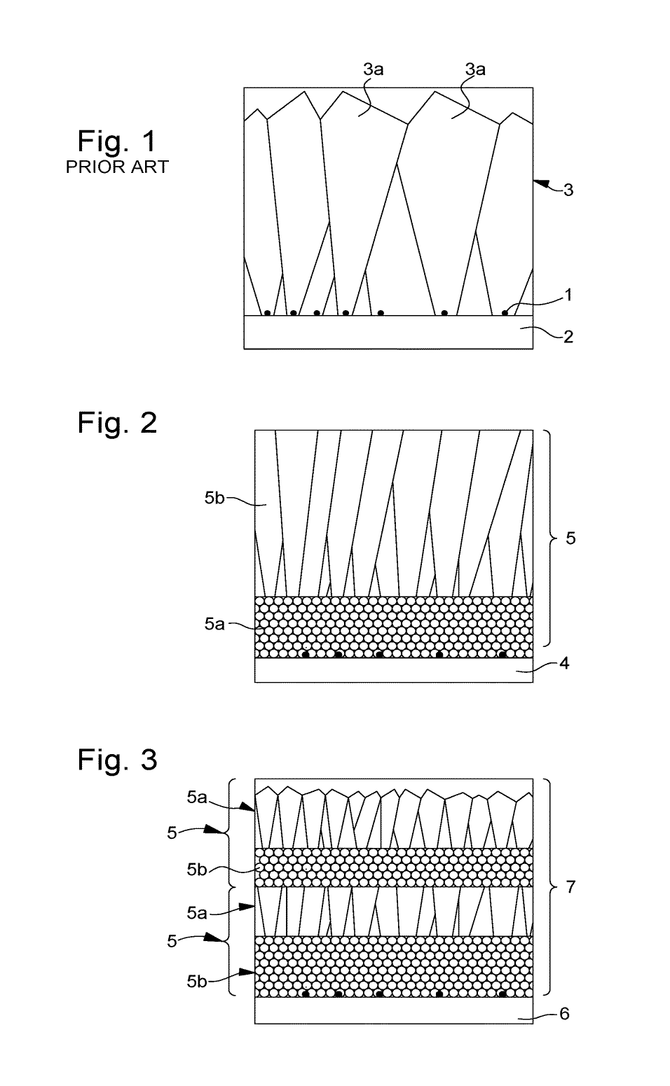

Referring to FIG. 1, there is seen a substrate 2 coated with a microcrystalline diamond coating 3 deposited in accordance with a conventional deposition method. It is to be noted that the microcrystalline growth is initiated by seeds 1, formed of diamond nanoparticles, distributed on the surface of substrate 2 and results in a layer formed of crystals having a pyramidal columnar geometry flaring away from the substrate surface. When the thickness of layer 3 increases, the crystal size increases and a growth in grain size ensues at the visible outer surface of the coating. This increase in grain size leads to an increase in roughness which may be undesirable depending on the application envisaged for the coating.

Referring to FIG. 2, there is seen a substrate 4 coated with a microcrystalline diamond coating 5 deposited according to the deposition method of the invention.

Unlike the prior art coating which is formed of single microcrystalline diamond layer 3, the monocrystalline diamond coating is formed of a stack of a first nanocrystalline diamond layer 5a and a second microcrystalline diamond layer 5b, as illustrated in FIG. 2.

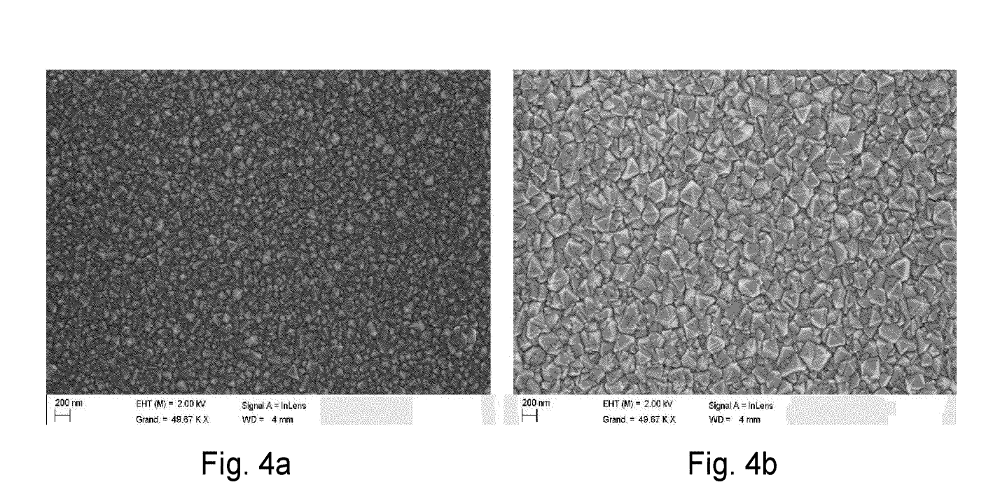

It is to be noted that with the same microcrystalline diamond coating surface thickness, the grain size at the visible outer surface of the coating is smaller and consequently roughness is decreased compared to prior art coatings. This is due to the fact that the nucleation for the microcrystalline diamond layer is created from the nanocrystalline diamond layer which is a closed layer, which offers a denser and more homogenous number of growth sites than conventional seeds formed of diamond nanoparticles which are simply distributed at the surface of the substrate to be coated. For example, with a nanocrystalline layer thickness on the order of 100 nanometres and a microcrystalline layer thickness on the order of 200 nanometres, the reduction in grain size obtained is on the order of 50% and the reduction in roughness Ra is on the order of 30%. This is clearly shown in FIGS. 4a and 4b.

Further, with an equal diamond coating thickness, the microcrystalline diamond layer of the coating of the invention is thinner than that of the prior art microcrystalline diamond coating, due to the stratified nature of the diamond coating of the invention. This reduction in thickness of the microcrystalline diamond layer in the diamond coating of the invention also contributes to the reduction in grain size and roughness Ra of the outer surface of the coating.

Referring to FIG. 3, there is seen a substrate 6 on which a variant embodiment of a coating 7 according to the invention has been deposited. In this variant, the coating comprises a succession of two stacks 5, like those described with reference to FIG. 2.

FIGS. 4a and 4b show scanning electron microscope photographs of top views of a substrate coated with a microcrystalline diamond coating wherein the final microcrystalline diamond layer was deposited in identical conditions (together in the same reactor), in accordance with the invention from a nanocrystalline layer (FIG. 4a) and in accordance with the prior art from diamond nanoparticles distributed at the surface of the substrate. It is clearly seen that the grain size of the coating layer of the invention is 50% smaller (typically 100 nanometres for a microcrystalline diamond layer thickness of 250 nanometres) than that of the prior art (typically 200 nanometres for a microcrystalline diamond layer thickness of 250 nanometres) and that roughness Ra of the coating layer of the invention is reduced by 30% compared to that of the prior art.

There will be described hereafter an example deposition of the microcrystalline diamond coating of the invention on a substrate formed of a silicon wafer comprising micromechanical parts to be coated, the latter being maintained on the wafer by breakable securing elements.

Coating 5 is deposited on substrate 4 by chemical vapour deposition (CVD) in a hot filament reaction chamber.

Prior to being placed in the reaction chamber, substrate 4 is cleaned in a hydrofluoric acid bath to remove the native oxide layer and enhance the attachment to its surface of diamond nanoparticles which will be used to grow the first nanocrystalline diamond layer.

Substrate 4 is then placed in a bath comprising a solvent, typically isopropanol and diamond nanoparticles in suspension. The size of the nanoparticles is typically comprised between 5 and 15 nanometres. The bath is then agitated by means of ultrasounds to attach the diamond nanoparticles to the surface of the substrate.

Substrate 4 is then air dried or in an inert gas flow, for example a nitrogen flow to finish the substrate preparation step.

The prepared substrate is then arranged in the reaction chamber on a stand, preferably allowing gases to flow freely around the substrate, and then the chamber is evacuated, typically with a vacuum of less than 1 mbar.

The substrate is then heated, directly via a heater and/or indirectly by heat radiated from the reactor filaments, to a deposition temperature.

Typically, the deposition temperature is comprised between 500 and 1000° C., for example a temperature on the order of 750°.

Once the deposition temperature is reached, a CH₄/H₂ gas mixture is injected into the reaction chamber. The percentage of CH₄ relative to the total volume is comprised between 3% and 9% and preferably 6%, and the hydrogen flow rate at 1 bar pressure is comprised between 20 and 50 litres per minute and preferably 40 litres per minute. The pressure of the gas mixture in the chamber is then comprised between 2 and 6 mbar and preferably 4 mbar. These conditions initiate the step of nucleation and nanocrystalline diamond growth from diamond nanoparticles and constitute the initial nucleation step.

The initial nucleation step conditions are then maintained in order to grow the nanocrystalline diamond layer at least on a thickness allowing the nanocrystalline diamond layer to form, typically over a thickness of 100 nanometres.

This thickness may of course vary and be up to a micron depending on the final coating hardness required to be obtained, although it is known that the hardness of the coating of the invention will be lower if the nanocrystalline diamond layer of the coating is of relatively large thickness.

The nanocrystalline diamond growth constitutes one phase of the diamond coating growth step of the invention.

Once the desired nanocrystalline diamond thickness is achieved, the conditions in the reaction chamber are modified in order to grow a microcrystalline diamond layer. To this end, the percentage of CH₄ relative to the total volume of CH₄/H₂ gas mixture is modified and changes to a value comprised between 0.05% and 1% and preferably 0.1% and the hydrogen flow rate at 1 bar pressure changes to a value comprised between 30 and 90 litres per minute and preferably 60 litres per minute.

The pressure of the gas mixture in the chamber is then returned to a value comprised between 0.5 and 2 mbar and preferably 1 mbar. In these deposition conditions, the diamond growth occurs in microcrystalline form, the grains of the subjacent nanocrystalline layer forming the seeds of the future microcrystalline layer.

The microcrystalline diamond layer growth phase is interrupted once the desired thickness is achieved. To obtain a microcrystalline diamond layer having a reduced surface grain size (typically on the order of 100 nanometres) and roughness Ra of less than 20 nm suitable for use in tribological applications, the thickness of the microcrystalline diamond layer should preferably not exceed 500 nm.

For applications in which a diamond coating thickness of more than 1 micrometre is desired, the sequence of successive depositions of nanocrystalline diamond and microcrystalline diamond layers will be repeated until the desired thickness is achieved.

It goes without saying that the invention is not limited to the embodiment that has just been described and that various simple modifications and variants may be envisaged by those skilled in the art without departing from the scope of the invention as defined by the annexed claims.

1. A micromechanical part comprising a substrate having a surface, wherein:
the surface comprises a diamond coating,
the diamond coating comprises a stack of a first nanocrystalline diamond layer with a grain size at the surface of less than 50 nanometers and a second microcrystalline layer with a grain size at the surface on the order of 100 nanometres, and
the diamond layer closest to the substrate is nanocrystalline and the diamond surface furthest from the substrate is microcrystalline.

2. The micromechanical part according to claim 1, wherein the diamond coating comprises a succession of at least two of the stacks wherein the microcrystalline diamond layer of a first stack is in contact with the nanocrystalline diamond layer of the next stack.

3. The micromechanical part according to claim 1, wherein a thickness of the nanocrystalline diamond layer is 50 nanometers to 1 micrometer.

4. The micromechanical part according to claim 1, wherein a thickness of the nanocrystalline diamond layer is 100 to 200 nanometers.

5. The micromechanical part according to claim 1, wherein a thickness of the microcrystalline diamond layer is 100 nanometers to 1 micrometer.

6. The micromechanical part according to claim 5, characterized in that the thickness of the microcrystalline diamond layer is comprised between 200 and 500 nanometres.

7. The micromechanical part according to claim 1, wherein the grain size of the nanocrystalline diamond layer at the surface is less than 30 nanometers.

8. The micromechanical part according to claim 1, wherein the grain size of the nanocrystalline diamond layer at the surface is less than 10 nanometers.

9. The micromechanical part according to claim 1, wherein the substrate comprises silicon, titanium, zirconium, hafnium, vanadium, tantalum, molybdenum, tungsten, boron; a boride, carbide, nitride or oxide thereof; or a ceramic.

10. The micromechanical part according to claim 1, wherein the part comprises a toothed wheel, a pinion, an escape wheel, a pallet-lever, a pallet-stone, a spring, a mainspring, a balance spring, an arbor and/or a pivot bearing.

11. A method for obtaining the micromechanical part according to claim 1, the method comprising:
a) preparing the substrate,
b) an initial nucleation, and
c) a sequence of two successive phases comprising a phase of nanocrystalline diamond growth to form a nanocrystalline diamond layer, followed by another phase of microcrystalline diamond growth, the nanocrystalline diamond layer being used as a nucleation layer for growth of the microcrystalline diamond layer.

12. The method according to claim 11, wherein c) is repeated a plurality of times.

13. The method according to claim 11, wherein during the nanocrystalline diamond layer growth phase of c), deposition parameters are set so that the nanocrystalline diamond grain size does not exceed 50.

14. The method according to claim 11, wherein a duration of the microcrystalline diamond growth phase of c) produces a microcrystalline diamond thickness of 100 nanometers to 1 micrometer.

15. The method according to claim 11, wherein a duration of the nanocrystalline diamond growth phase of c) produces a nanocrystalline diamond thickness of 100 to 200 nanometers.

16. The method according to claim 11, wherein the substrate comprises silicon, titanium, zirconium, hafnium, vanadium, tantalum, molybdenum, tungsten, boron; a boride, carbide, nitride or oxide thereof; or a ceramic.

17. The method according to claim 11, implemented in a hot filament reactor.

18. The method according to claim 11, wherein a temperature of the substrate during c) is from 500 to 1000° C.

19. The method according to claim 1, wherein the nanocrystalline diamond growth phase is implemented in the following conditions:
a duration of 1 hour to 5 hours,
heating, respectively direct or indirect activation, of a CH₄/H₂/X gas mixture wherein X represents a dopant gas, with a percentage by volume of dopant gas of 0% to 10%, and with a percentage by volume of CH₄, relative to the total volume, of 3% to 9%,
a hydrogen flow rate at 1 bar pressure is 20 to 50 liters per minute,
a pressure of the gas mixture in the chamber is 2 to 6 mbar, and
a temperature of the substrate is 500 to 1000° C.

20. The method according to claim 11, wherein the microcrystalline diamond growth phase is implemented in the following conditions:
a duration of 1 hour to 5 hours,
heating, respectively direct or indirect, of a CH₄/H₂/X gas mixture wherein X represents a dopant gas, with a percentage by volume of dopant gas of 0% to 10%, and with a percentage by volume of CH₄. relative to the total volume, of 0.05% to 1%,
a hydrogen flow rate at 1 bar pressure is 30 to 90 liters per minute,
a pressure of the gas mixture in the chamber is 0.5 to 2 mbar, and
a temperature of the substrate 500 to 1000° C.
